(19) United States
(12) Patent Application Publication
(10) Pub. No.: US 2010/0326602 A1
(43) Pub. Date: Dec. 30, 2010

(54) ELECTROSTATIC CHUCK

(75) Inventors: Terry BLUCK, Santa Clara, CA (US); Terry Pederson, Sunnyvale, CA (US); Dennis Grimard, Ann Arbor, MI (US)

Correspondence Address: NIXON PEABODY, LLP, 401 9TH STREET, NW, SUITE 900, WASHINGTON, DC, 20004-2128, US

(73) Assignee: INTEVAC, INC., Santa Clara, CA (US)

(21) Appl. No.: 12/495,252

(22) Filed: Jun. 30, 2009

(51) Int. Cl. H01L 21/683; H01L 21/3065; B05C 13/02

(52) U.S. Cl. 156/345.53; 361/234; 118/500

(57) ABSTRACT

An isolator for heat transfer gas conduits of an electrostatic chuck is described. The isolator includes a sleeve and a body positioned in the sleeve to form an annulus between the body and sleeve that allows for flow of the heat transfer gas. The body is positioned against the puck of the chuck, and may be supported in this position by a spring. A silicon seal may be provided between the sleeve and the puck to prevent plasma from forming in the conduits.

### BACKGROUND

1. Field

The subject invention relates to the field of substrate processing and in particular to an electrostatic chuck.

2. Related Art

An electrostatic chuck is used to electrostatically hold a substrate during processing (e.g., to hold a silicon wafer in a chamber during semiconductor processing). The electrostatic chuck assembly typically includes an electrostatic chuck electrode covered by a dielectric, which is positioned over a cooling base. The electrostatic chuck assembly is then positioned over a cathode and an insulator. The electrostatic chuck assembly is positioned in a plasma chamber in which plasma is generated. The plasma is an electrically conductive gaseous medium that may be formed by coupling electromagnetic energy, such as RF energy, to the gas. There are several different methods for generating the plasma and holding the substrate to the electrostatic chuck. For example, a DC voltage may be applied to the electrostatic chuck electrode while an RF voltage is applied to the cathode, or a DC voltage may be applied to the electrostatic chuck electrode and RF voltage is applied to both the electrostatic chuck electrode and the cathode.

A heat transfer gas, such as helium, may also be provided to the backside of the substrate via conduits and apertures that extend through the electrostatic chuck assembly (apertures through the dielectric and electrode and conduits through the cooling base) to remove heat from the substrate. Because the electrostatic chuck delivers both DC and RF power to the wafer, intense electric fields are generated proximate these apertures and conduits. These fields are necessary to generate the plasma and chuck the wafer.

The fields can permeate into, or may form in, the apertures and conduits in the electrostatic chuck assembly. In particular, the potential applied to the electrostatic chuck electrode may cause the formation of glow discharges or electrical arcing in or about the helium gas apertures and conduits passing through the electrostatic chuck assembly. This is especially a problem when the gas apertures and conduits extend through an electrostatic chuck electrode of the electrostatic chuck assembly that is powered with a RF voltage, for example, to ignite or sustain the plasma in the chamber. This RF voltage may permeate and couple to the gas traveling through the gas apertures to generate plasma in the apertures. The plasma in the apertures sputters ceramic particles off of the walls of the apertures, and can enter and contaminate the processing chamber and/or the wafer. In addition, the plasma may heat the aperture or generate sufficient current to heat the aperture creating excessive stress in the electrostatic chuck assembly that can result in failure. Also, the plasma can degrade the standoff voltage of the electrostatic chuck assembly.

Designing an electrostatic chuck assembly that can deliver sufficient helium with a low pressure drop while isolating the conductive electrical components from one another constitutes a significant challenge. The primary tradeoff is between delivering sufficient helium to the surface of the electrostatic chuck assembly and providing gaps that do not allow the helium gas to ignite via an electron to atom pathway driven by the intense fields permeating the chuck and voids in the chuck which allow for helium movement. Thus, it is desirable to have an electrostatic chuck assembly capable of reducing plasma formation about or in the electrostatic chuck, for example, in the apertures and conduits extending through the electrostatic chuck assembly, while also delivering a sufficient amount of heat transfer gas to the substrate.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

According to an aspect of the invention, an isolator is provided that is positionable in a heat transfer gas conduit of an electrostatic chuck and includes a sleeve; and a body positionable in the sleeve to form an annulus between the body and the sleeve, the annulus configured to deliver a heat transfer medium to a top surface of the electrostatic chuck.

The isolator may also include a spring to push the body against a surface of a ceramic puck of the electrostatic chuck.

The isolator may also include a seal between the isolator and the electrostatic chuck.

The seal may include a thermally conductive and electrically insulating silicone.

The plug may further include transfer slits configured to supply the heat transfer gas to a delivery aperture in a ceramic puck of the electrostatic chuck.

The sleeve and the body may be ceramic.

According to another aspect of the invention, an electrostatic chuck is provided that includes a base; a dielectric over the base, the dielectric comprising an electrode and a puck over the electrode; a plurality of apertures in the puck; a plurality of heat transfer conduits in the base, the heat transfer conduits in fluid communication with the plurality of apertures; and, a plurality of isolators in the plurality of heat transfer conduits, each of the plurality of isolators comprising a sleeve, a body and an annulus between the sleeve and the body, the annulus configured to deliver a heat transfer medium to the plurality of apertures.

The electrostatic chuck may also include a seal between each of the sleeves and the puck.

The seal may include a thermally conductive and electrically insulating silicone.

The electrostatic chuck may also include a plurality of springs in the base, each spring configured to position a top surface of the body against a bottom surface of the puck.

The body may also include transfer slits in fluid communication with the plurality of apertures.

The electrostatic chuck may also include a plenum between the transfer slits and the plurality of apertures, and wherein the plenum is in fluid communication with the transfer slits and the plurality of apertures.

The plurality of isolators may be ceramic.

According to a further aspect of the invention, a substrate processing system is provided that includes a puck comprising a plurality of apertures; and a cooling base comprising a plurality of heat transfer gas channels and a plurality of isolators in the plurality of heat transfer channels in fluid communication with a heat transfer gas source, each of the plurality of isolators comprising a sleeve, a body and an annulus between the sleeve and the body, the plurality of apertures in fluid communication with the annulus of each of the plurality of isolators.

The substrate processing system may also include a seal between each of the sleeves and the electrostatic chuck.

The seal may include a thermally conductive and electrically insulating silicone.

The substrate processing system may also include a plurality of springs in the cooling base, each spring configured to position a top surface of each of the plurality of plugs against the puck.

Each of the plurality of isolators may include transfer slits in fluid communication with the annulus and the plurality of apertures.

The substrate processing system may also include a plenum between and in fluid communication with the transfer slits and the plurality of apertures.

The plurality of plugs may be ceramic.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 is a perspective view of a substrate processing chamber in accordance with one embodiment of the invention;

FIG. 2A is a side view of an electrostatic chuck in accordance with one embodiment of the invention;

FIG. 2B is a top view of an electrostatic chuck in accordance with one embodiment of the invention;

FIG. 3 is a detailed side view of an electrostatic chuck with an isolator in a conduit of the electrostatic chuck in accordance with one embodiment of the invention;

FIGS. 4A-4C are detailed views of an isolator in accordance with one embodiment of the invention; and

FIGS. 5A-5C are detailed views of an isolator in accordance with another embodiment of the invention.

### DETAILED DESCRIPTION

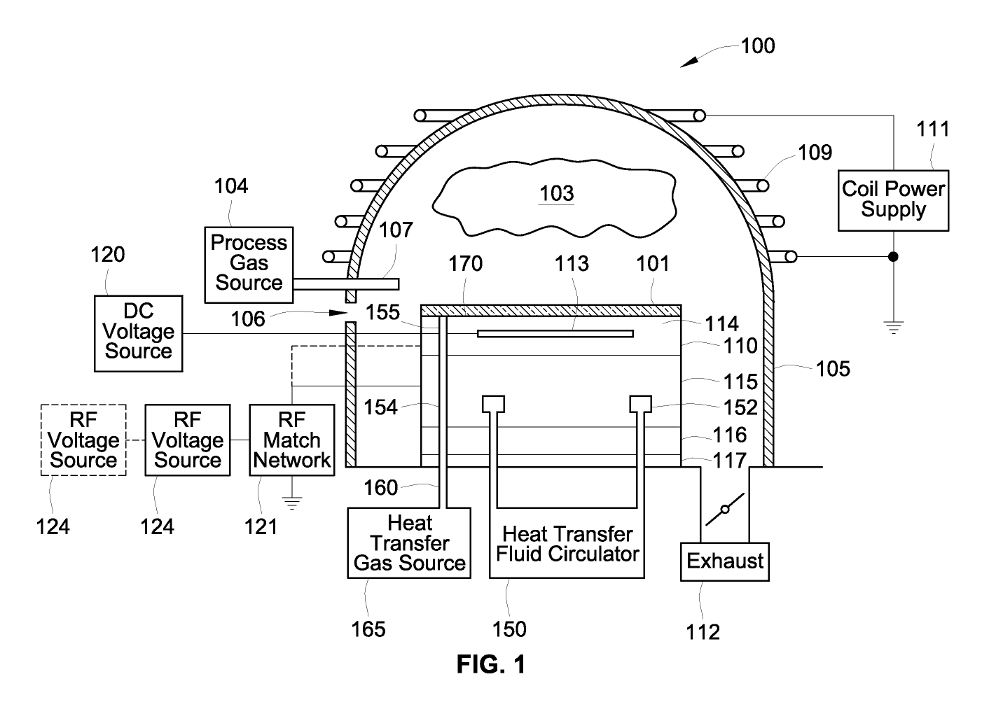

An embodiment of the invention will now be described in detail with reference to FIG. 1. FIG. 1 illustrates a vacuum chamber 100 having an electrostatic chuck 110. It will be appreciated that the configuration shown in FIG. 1 is merely exemplary. The vacuum chamber 100 and electrostatic chuck 110 may have additional or fewer components, and the arrangement of the components may vary, as known to those of skill in the art.

In FIG. 1, a wafer 101 is shown secured to the chuck 110 in the vacuum chamber 100. The illustrated vacuum chamber 100 is configured for plasma processing (e.g., plasma 103 is shown in the chamber 100). Plasma processing includes, for example, etching, plasma enhanced chemical vapor deposition (PECVD), and the like. It will be appreciated that the vacuum chamber may be any type of vacuum chamber that includes an electrostatic chuck, and, therefore, other processes can be performed in the chamber. It will also be appreciated that the vacuum chamber may be a capacitively-coupled plasma (CCP) chamber or, for example, an inductively-coupled plasma (ICP) source chamber. Vacuum chambers that employ sources to increase the plasma density and decouple the ion energy from ion generation are often referred to as high density plasmas (HDP) chambers. It will be appreciated that the vacuum chamber may be an HDP chamber; exemplary HDP sources include microwave, inductive, and helicon sources. It will also be appreciated that the HDP chamber need not decouple the ion energy from ion generation.

The vacuum chamber 100 includes a vacuum-tight enclosure 105. The enclosure 105 may be made of aluminum, stainless steel or other vacuum-compatible materials. The enclosure 105 may be electrically grounded, in which case the chamber wall is an anode. A slit valve 106 is provided to allow the wafer to enter and exit the vacuum-tight enclosure 105. A valve 107 is also provided to allow gases from a process gas source 104 to enter the enclosure 105. An inductor coil 109 may be provided adjacent to the chamber 100 and powered by a coil power supply 111 to form plasma from the gas. The chamber 100 also includes a throttled exhaust 112 for exhausting gaseous byproducts.

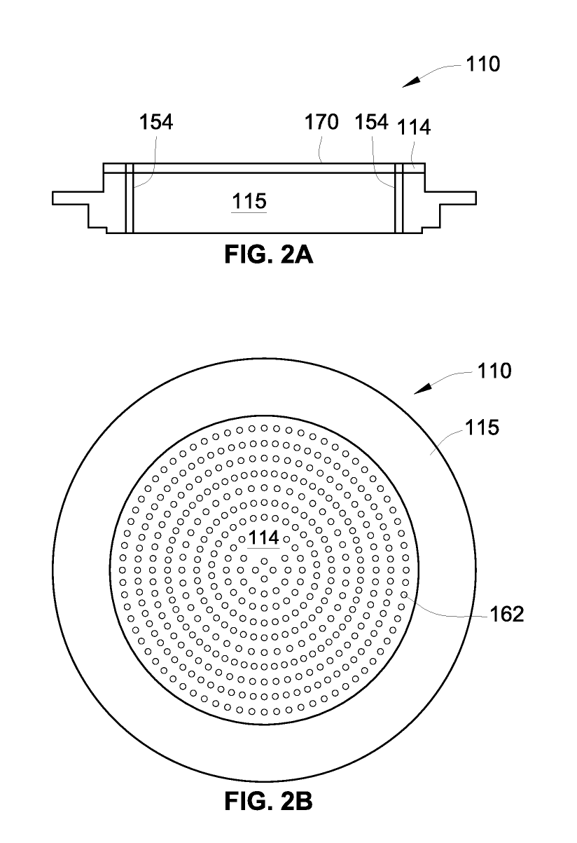

With reference to FIGS. 1 and 2A-2B, the electrostatic chuck assembly 110 includes a dielectric puck 114 and a cooling base 115. The dielectric puck 114 includes an electrode 113 which is covered by or embedded in a dielectric 118 that electrically isolates the electrode 113 from the substrate 101. The electrode 113 includes a metal layer composed of copper, nickel, chromium, aluminum, molybdenum, tungsten or alloys thereof. It will be appreciated that the electrostatic chuck assembly 110 may be a monopolar, biopolar, or multipolar chuck. The cooling base 115 supports the dielectric puck 114, and the cooling base 115 is supported by a cathode 116 which is coupled to an insulator 117.

A heat transfer fluid circulator 150 circulates heat transfer fluid through channels 152 in the base 115 to transfer heat to or from the dielectric puck 114. One or more heat transfer gas conduits 154 extend through the cooling base 115 and one or more heat transfer apertures 155 extend through the dielectric puck 114. Gas supply channel 160, connected to a heat transfer gas source 165, supplies heat transfer gas to the conduits 154 which supply heat transfer gas to the apertures 155. Typically, the heat transfer gas is helium or argon. The gas conduits 154 and apertures 155 are configured to deliver the gas to a top surface 170 of the dielectric 114. The gas provided to the top surface 170 may be used to regulate the temperature of the substrate 101 by transferring heat to or from the substrate 101. In an electrostatic chuck assembly 110 used with a 300 mm (12 inch) silicon wafer, the number of outlets for the gas apertures 155 may range from about 1 to about 200, and the outlets may be positioned in a ring-shaped configuration around the perimeter of the dielectric puck 114.

The substrate 101 held on the dielectric puck 114 covers and seals the edges of the dielectric 114 to reduce leakage of heat transfer gas from the peripheral edge of the dielectric puck 114. The dielectric 114 can also include mesas 162 that are sized and distributed to stand off the substrate to allow heat transfer gas to be evenly distributed such that substantially the entire surface of the substrate 101 is uniformly heated or cooled.

Referring back to FIG. 1, the chuck electrode 113 is connected to a DC voltage supply 120. An RF Match Network 121, which is connected to an RF voltage source 124, is connected to the cathode 116. It will be appreciated that different electrostatic chuck assemblies may be used in which the DC voltage supply and RF Match Network and RF voltage source may be connected to the electrode and/or cathode in a different configuration than shown in FIG. 1. It will be appreciated that multiple RF power supplies may be used to excite the plasma. In one example, a first RF power supply may be operated at a first frequency, while a second RF power supply may be operated at a second frequency. The frequency range of the RF powers may be any value or range of values between about 100 kHz and 100 MHz.

In operation, a robot arm (not shown) moves the wafer 101 into the chamber 100 through the slit valve 106. Then, either a chucking voltage is applied to the wafer and the plasma is activated, or the plasma is activated and the chucking voltage is applied. The chucking voltage is applied to the wafer 101 by providing a voltage to the electrode 113 using the DC voltage supply 120. The chucking voltage is set to a value high enough to produce an electrostatic force between the wafer and the chuck adequate to prevent wafer movement during subsequent process steps. For example, the chuck voltage may be any value or range of values between about −5000V to +5000V (e.g., −5000V to +5000V for a coulombic chuck and −1000V to +1000V for a JR-type chuck, etc). The RF voltage source 124 applies RF voltage to the cathode 116 and coil power supply 111 supplies RF power to the inductor coil 109 to excite the plasma 103 in the chamber 100.

After the wafer 101 is chucked, one or more semiconductor fabrication process steps are performed in the chamber 100, such as deposition or etching films on the wafer. After completion of the semiconductor fabrication process, the wafer is dechucked and can then be removed from the chamber for additional processing.

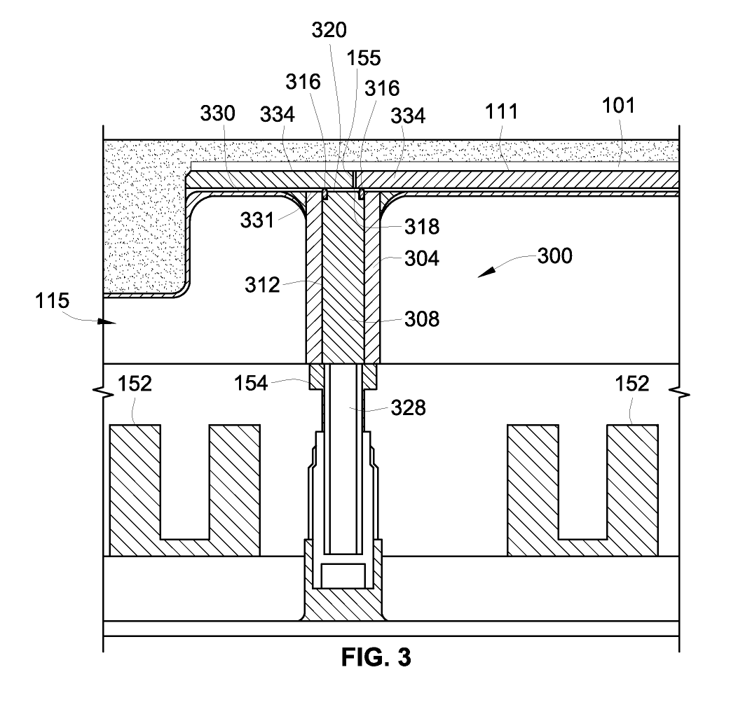

Referring to FIGS. 3-5, an isolator 300 is located in each of the gas conduits 154 to reduce or prevent plasma formation from the gas provided by the conduit 154. This version of the electrostatic chuck assembly 110 is useful for holding wafers in high density plasma environments. High density plasmas typically contain a higher ion density. Charged plasma species in thin plasma sheaths typically have ion energies in excess of 1,000 eV. The isolator 300 reduces or altogether prevents formation of a plasma about or in the conduits 154.

As shown in FIG. 3, the isolator 300 includes a sleeve 304, which is positioned in the heat transfer gas conduit in the cooling base 115. A body 308 is provided in the sleeve 304 such that an annulus 312 is formed between the sleeve 304 and the body 308. In one embodiment, the body 308 is positioned in the sleeve 304 with a nearly line-to-line fit (e.g., 50 microns on the diameter). The annulus 312 is fluidly coupled to the gas supply conduit 154, such that the heat transfer gas is fed through from the bottom of the body 308 to allow the heat transfer gas to be conducted into the annulus 312. The annulus 312 is, therefore, large enough to allow for sufficient helium flow while suppressing the arcing potential.

The sleeve 304 and body 308 may be fabricated from any dielectric material, including ceramics and thermoplastics or thermoset polymers. Exemplary polymers include but are not limited to polyimide, polyoxymethylene, polyacetal, polytetrafluoroethylene, polyetherimide, and silicone and the like. It will be appreciated that polymers that have a high stand off voltage, low dielectric constant, and high resistivity can be used. Exemplary suitable ceramic materials include but are not limited to Al₂O₃, AlN, SiO₂, Si₃N₄, and the like.

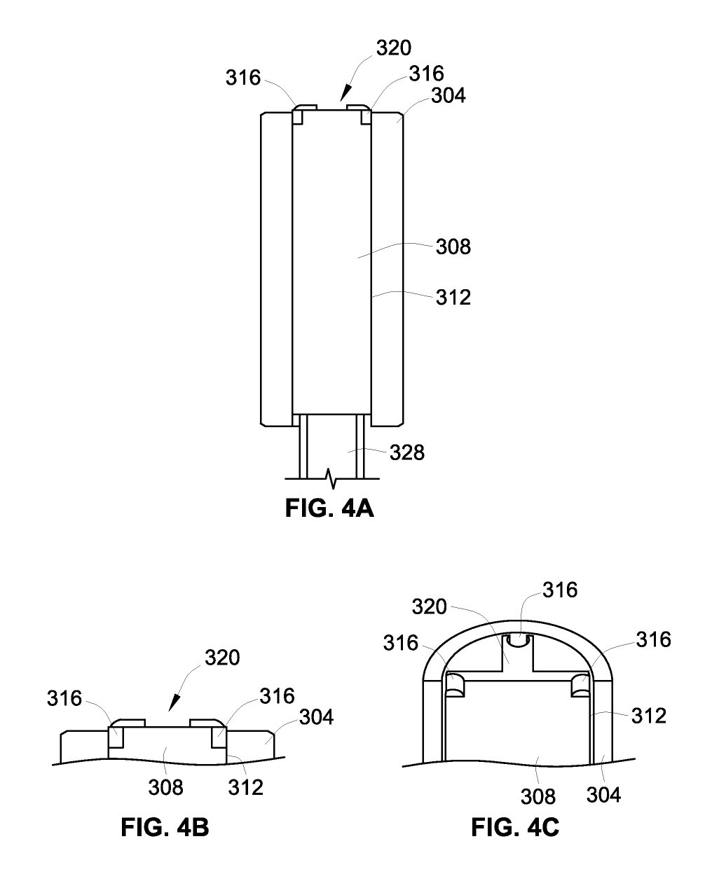

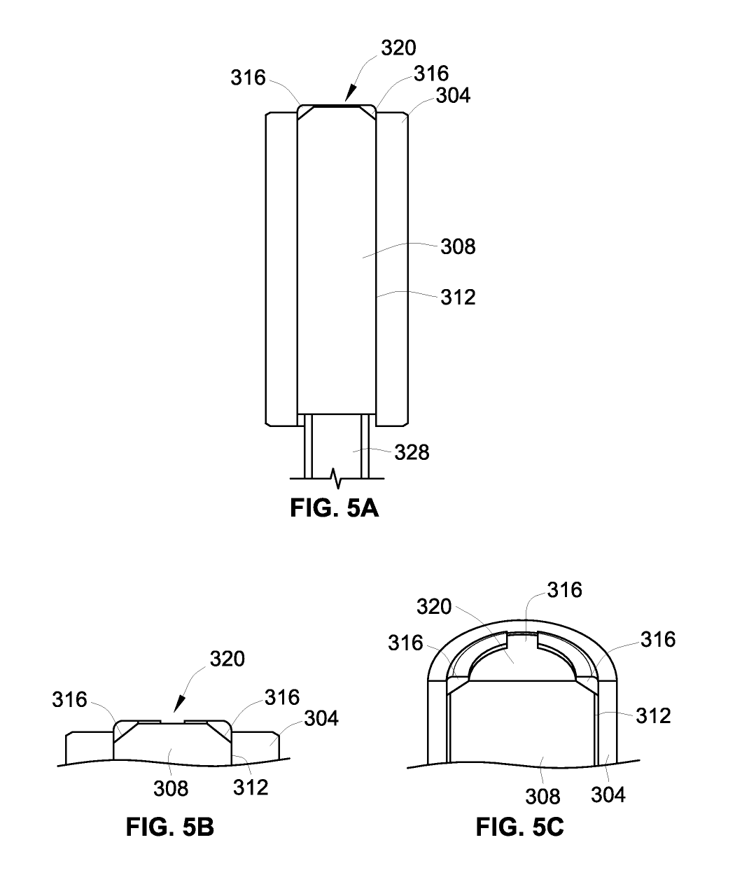

As shown in detail in FIGS. 4 and 5, transfer slits 316 are provided on a top surface 318 of the body 308 to allow for passage of the heat transfer gas from the annulus 312 to a plenum 320 that is formed between the top surface 318 of the body 308 and a bottom surface of the dielectric puck 114. In one embodiment, the plenum 320 is about 100 microns deep and a few mm in diameter. FIGS. 4A-4C illustrate an embodiment in which the transfer slits 316 are generally tubular, while FIGS. 5A-5C illustrate an embodiment in which the transfer slits 316 are generally polygonal. It will be appreciated that the transfer slits 316 may have different configurations than those illustrated in FIGS. 4 and 5.

With reference back to FIG. 3, an aperture 155 is provided through the dielectric puck 114 to deliver the heat transfer gas from the isolator 300 to the wafer 101 via the plenum 320 and annulus 312. In one embodiment, the aperture 155 is about 100 to about 1000 microns in diameter.

A spring mechanism 328 may be provided to position the top surface 318 of the body 308 tight against the bottom surface 330 of the puck 114. The spring 328 is configured to help seal the plenum 320 between the top surface 318 of the body 308 and the puck 114.

A seal 334 is provided to seal the sleeve 304 to the cooling base 115. In one embodiment, the seal 334 is a thermally conductive and electrically insulating silicone seal. It will be appreciated however that the seal 334 may be other pliable materials that are electrically insulating and thermally conducting. During assembly, a small gap may be provided between the top of the sleeve 304 and the bottom surface 330 of the puck 114 to allow for infiltration of the silicone (or other sealing material) between the top surface 331 of the sleeve 304 and the bottom surface 330 of the puck 114. In one embodiment, access to the silicone (or other sealing material) is provided from the bottom of the isolator 300 (i.e., the cooling base 115) to remove excess silicone from the inner diameter of the sleeve 304 during assembly. The transfer slits 316 allow the heat transfer gas to be transferred without blockage by the seal 334. In one embodiment, the thickness of the seal 334 is about 100-200 microns.

In use, the heat transfer gas enters the annulus 312 through the cooling base 115 at the bottom of the body 308. The heat transfer gas travels up through the annulus 312 and through the transfer slits 316 into the plenum 320. The heat transfer gas then travels from the plenum 320 and into the aperture 155 in the puck 114. Because the top portion of the isolator 300 is sealed via the seal 334 and the spring 328, electron excitement at the near the top of the body 308 is prevented. The transfer slits 316 allow the helium to pass by the silicon seal 334 into the plenum 320 and then the aperture 155 without compromising the arc suppression of the isolator 300.

Embodiments of the invention are advantageous because they provide improved electrical characteristics while also delivering sufficient heat transfer gas to the wafer. For example, the isolator as illustrated above may deliver +/−3 KV of electrical standoff while delivering more than 2 sccm of heat transfer gas (e.g., helium) per aperture (i.e., a 50% increase in stand-off voltage compared to conventional electrostatic chuck designs).

It will be appreciated that the isolator 300 may also comprise a plasma-deactivating material that is capable of deactivating, and consequently preventing, formation of a plasma adjacent to the gas conduit 154 below the wafer 101. The plasma-deactivating material may comprise a porous or high surface area material that prevents plasma formation by limiting the kinetic energy and/or dissipating the electrical charge of gaseous species that may become ionized in the conduits.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

What is claimed is:

1. An isolator positionable in a heat transfer gas conduit of an electrostatic chuck comprising:
a sleeve; and
a body positionable in the sleeve to form an annulus between the body and the sleeve, the annulus configured to deliver a heat transfer medium to a top surface of the electrostatic chuck.

2. The isolator of claim 1, further comprising a spring to push the body against a surface of a dielectric puck of the electrostatic chuck.

3. The isolator of claim 1, further comprising a seal between the sleeve and the electrostatic chuck.

4. The isolator of claim 3, wherein the seal comprises a thermally conductive and electrically insulating silicone.

5. The isolator of claim 1, wherein the body further comprises transfer slits configured to supply the heat transfer gas to a delivery aperture in a dielectric puck of the electrostatic chuck.

6. The isolator of claim 1, wherein the sleeve and the body are dielectric.

7. An electrostatic chuck comprising:
a cooling base;
a puck over the cooling base, the puck comprising an electrode and a dielectric at least partially around the electrode;
a plurality of apertures in the puck;
a plurality of heat transfer conduits in the cooling base, the heat transfer conduits in fluid communication with the plurality of apertures;
a plurality of isolators in the plurality of heat transfer conduits, each of the plurality of isolators comprising a sleeve, a body and an annulus between the sleeve and the body, the annulus configured to deliver a heat transfer medium to the plurality of apertures.

8. The electrostatic chuck of claim 7, further comprising a seal between each of the sleeves and the puck.

9. The electrostatic chuck of claim 7, wherein the seal comprises thermally conductive and electrically insulating silicone.

10. The electrostatic chuck of claim 7, further comprising a plurality of springs in the base, each spring configured to position a top surface of the body against a bottom surface of the puck.

11. The electrostatic chuck of claim 7, wherein the body further comprises transfer slits in fluid communication with the plurality of apertures.

12. The electrostatic chuck of claim 11, further comprising a plenum between the transfer slits and the plurality of apertures, and wherein the plenum is in fluid communication with the transfer slits and the plurality of apertures.

13. The electrostatic chuck of claim 7, wherein the plurality of isolators are ceramic.

14. A substrate processing system comprising:
a puck comprising a plurality of apertures; and
a cooling base comprising a plurality of heat transfer gas channels and a plurality of isolators in the plurality of heat transfer channels in fluid communication with a heat transfer gas source, each of the plurality of isolator comprising a sleeve, a body and an annulus between the sleeve and the body, the plurality of apertures in fluid communication with the annulus of each of the plurality of isolator.

15. The substrate processing system of claim 14, further comprising a seal between each of the sleeves and the electrostatic chuck.

16. The substrate processing system of claim 15, wherein the seal comprises thermally conductive and electrically insulating silicone.

17. The substrate processing system of claim 14, further comprising a plurality of springs in the cooling base, each spring configured to position a top surface of each of the plurality of plugs against the puck.

18. The substrate processing system of claim 14, wherein each of the plurality of plugs comprises transfer slits in fluid communication with the annulus and the plurality of apertures.

19. The substrate processing system of claim 18, further comprising a plenum between and in fluid communication with the transfer slits and the plurality of apertures.

20. The substrate processing system of claim 14, wherein the plurality of isolators are ceramic.
